(19) United States
(12) Patent Application Publication
(10) Pub. No.: US 2009/0128170 A1
(43) Pub. Date: May 21, 2009

(54) PRINT MEDIA DETECTING MODULE

(76) Inventor: Tsung-Yueh Chen, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/051,860

(22) Filed: Mar. 20, 2008

(30) Foreign Application Priority Data
Nov. 20, 2007 (TW) 096143892

(51) Int. Cl. G01R 27/08

(52) U.S. Cl. 324/713; 324/691

(57) ABSTRACT

A print medium detecting module includes a first conductive unit, a second conductive unit and a detector. The first conductive unit is coupled to a first reference voltage level. The detector has a detecting port, which is coupled to the second conductive unit and a second reference voltage level, for referring to an electrical characteristic of the detecting port to detect whether there is a non-conductive print media between the first and second conductive units that causes the first conductive unit to not be electrically connected to the second conductive unit. The first and second conductive units in an initial state are electrically connected to each other. The first reference voltage level is different from the second reference voltage level.

### BACKGROUND OF THE INVENTION

1. Field of the Invention

The present invention relates to a print media detecting module, and more particularly, to a print media detecting module having a first conductive unit, a second conductive unit and a detector. The detector refers to an electrical characteristic of a detecting port to detect whether there is a non-conductive print media between the first and second conductive units.

2. Description of the Prior Art

In general, color printers can be classified into four major types: dot matrix printers, inkjet printers, laser printers and dye diffusion thermal printers. The dye diffusion thermal printer utilizes a thermal print head to heat ribbons containing dyes in order to transfer the dyes onto an object to be printed. In this way, continuous-tone can be formed on the object according to the heating time or the heating temperature. Due to its excellent printing quality and the natural, continuous color expression, the thermal printer is particularly suitable for photo printing applications.

The present dye diffusion thermal transfer printer uses active sensors to detect whether there is a print media, such as paper or card, in the printer. The active sensor primarily comprises a transmitter and a receiver, and is classified into two types: a reflective sensor and an interruptive sensor. Please refer to FIG. 1. FIG. 1 is a diagram illustrating the operation of a typical reflective sensor 100. As shown in FIG. 1, the typical reflective sensor 100 comprises a transmitter 110 and a receiver 120. Under normal circumstances, the transmitter 110 emits a light beam 10 (as shown in sub-figure A). When a print media 20 is entered, the light beam 10 is reflected by the print media 20 and received by the receiver 120 (as shown in sub-figure B). In this scenario, the reflective sensor 100 detects the print media 20. Please refer to FIG. 2. FIG. 2 is a diagram illustrating operation of a typical interruptive sensor 200. As shown in FIG. 2, the typical interruptive sensor 200 also comprises a transmitter 210 and a receiver 220. Under normal circumstances, the transmitter 210 emits a light beam 10 that is received by the receiver 220 (as shown in sub-figure A). When a print media 20 is entered, the light beam 10 is blocked by the print media 20 (as shown in sub-figure B). In this scenario, the interruptive sensor 200 detects the print media 20.

However, if a print media is made of a transparent material such as a transparent card, neither the reflective nor interruptive sensor can detect the transparent print media since the print media is unable to reflect or block the light beam. This results in dye diffusion thermal transfer printers being unable to print the transparent print media correctly.

### SUMMARY OF THE INVENTION

It is therefore one of the objectives of the present invention to provide a print media detecting module having two conductive units and a detector. The print media detecting module refers to an electrical characteristic to detect whether there is a non-conductive print media between the first and second conductive units, to resolve the above-mentioned problem.

According to an exemplary embodiment of the present invention, a print media detecting module is disclosed. The print media detecting module comprises: a first conductive unit, a second conductive unit and a detector. The first conductive unit is coupled to a first reference voltage level. The detector has a detecting port, which is coupled to the second conductive unit and a second reference voltage level. The detector is used for referring to an electrical characteristic of the detecting port to detect whether there is a non-conductive print media between the first and second conductive units that causes the first conductive unit to not be electrically connected to the second conductive unit. The first and second conductive units in an initial state are electrically connected to each other, and the first reference voltage level is different from the second reference voltage level.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating operation of a typical reflective sensor.

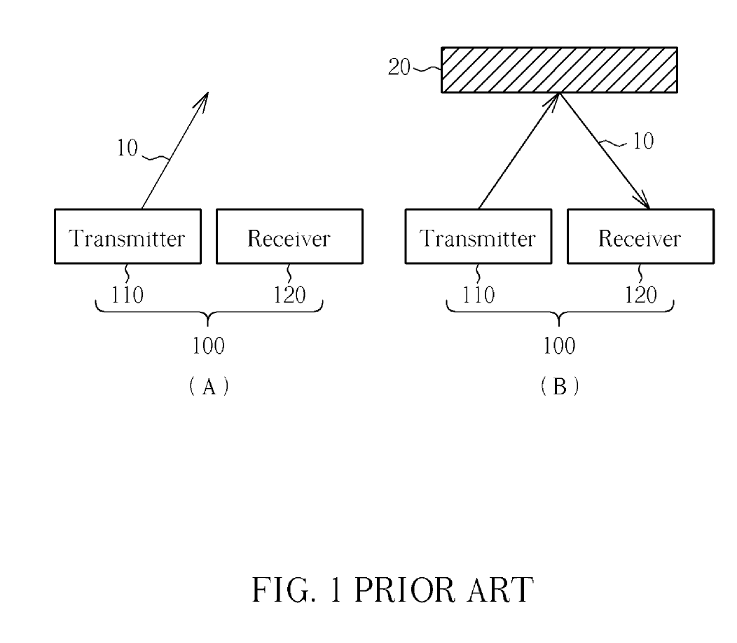

FIG. 2 is a diagram illustrating operation of a typical interruptive sensor.

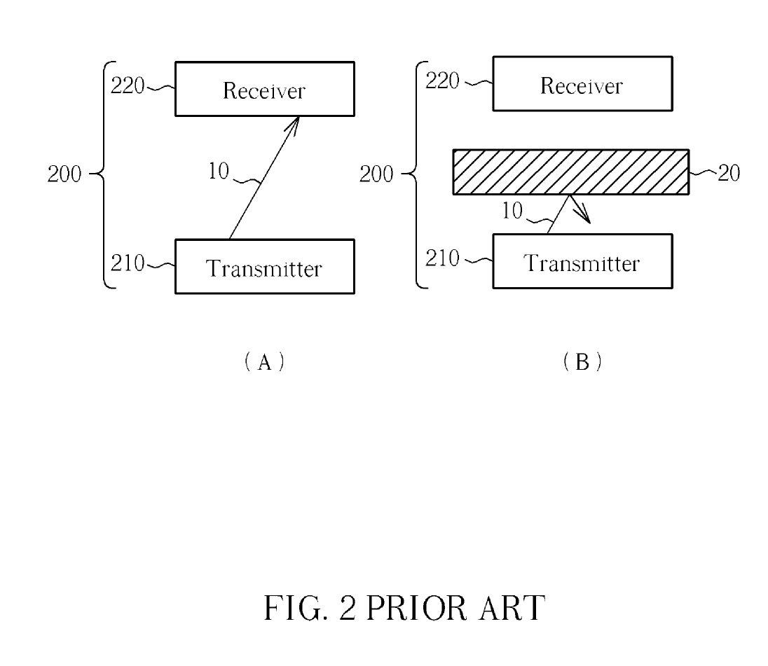

FIG. 3 is a diagram illustrating a print media detecting module according to an embodiment of the present invention.

FIG. 4 is a diagram illustrating that there is a non-conductive print media in the print media detecting module.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”.

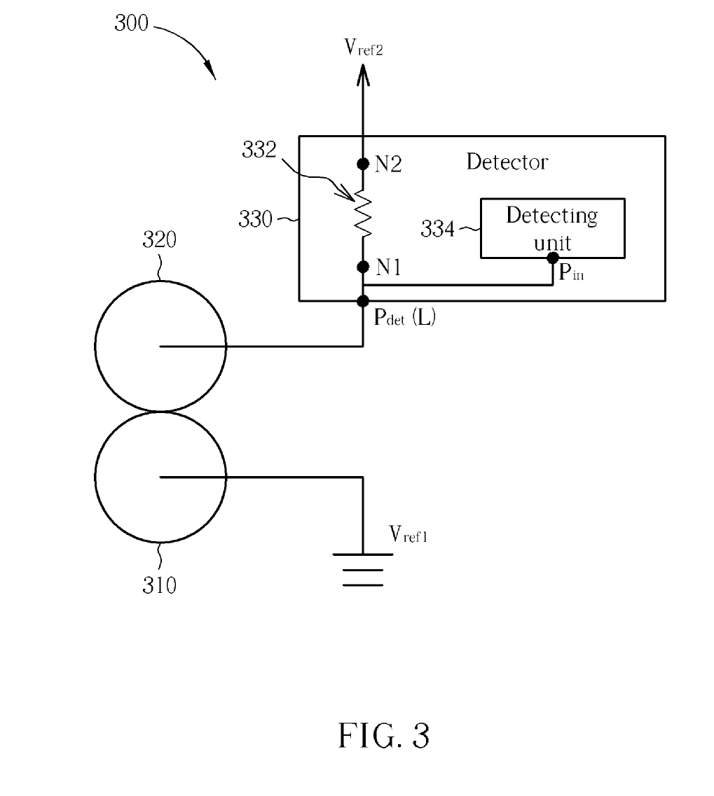

Please refer to FIG. 3. FIG. 3 is a simplified diagram illustrating a print media detecting module 300 according to an embodiment of the present invention. As shown in FIG. 3, the print media detecting module 300 comprises (but is not limited to) a first conductive unit 310, a second conductive unit 320 and a detector 330. The first conductive unit 310 is coupled to a first reference voltage level Vref1. The second conductive unit 320 is coupled to a detecting port Pdet of the detector 330, and the detecting port Pdet is coupled to a second reference voltage level Vref2, which is different from the first reference voltage level Vref1. In this embodiment, the first and second conductive units 310, 320 in an initial state are electrically connected to each other. The detector 330 refers to an electrical characteristic of the detecting port Pdet to detect whether there is a non-conductive print media between the first and second conductive units 310, 320 that causes the first conductive unit 310 to not be electrically connected to the second conductive unit 320.

In this embodiment, the print media detecting module 300 is disposed in a dye diffusion thermal transfer printer for detecting whether there is a non-conductive print media entered into the dye diffusion thermal transfer printer; this is, however, for illustrative purposes and not a limitation of the prevent invention. In practice, the print media detecting module of the present invention can be disposed in any other apparatus that require detecting non-conductive print medias, such as other types of printer or copier.

Please refer to FIG. 3 again. The detector 330 in the print media detecting module 300 comprises an impedance unit 322 and a detecting unit 334. In this embodiment, the impedance unit 332 is a resistor; this is, however, for illustrative purposes and not a limitation of the prevent invention. The impedance unit 322 has a first end N1 and a second end N2. The first end N1 is coupled to the detecting port Pdet, and the second end N2 is coupled to the second reference voltage level Vref2. The detecting unit 334, such as a microcontroller, has an input end Pin coupled to the detecting port Pdet for referring to the electrical characteristic of the detecting port Pdet to detect whether there is a non-conductive print media entered between the first and second conductive units 310, 320. In this embodiment, the electrical characteristic detected by the detecting unit 334 is a voltage level. In other words, the detecting unit 334 refers to the voltage level of the detecting port Pdet to detect whether there is a non-conductive print media entered between the first and second conductive units 310, 320. The further operations of the print media detecting module 300 will be explained in the following.

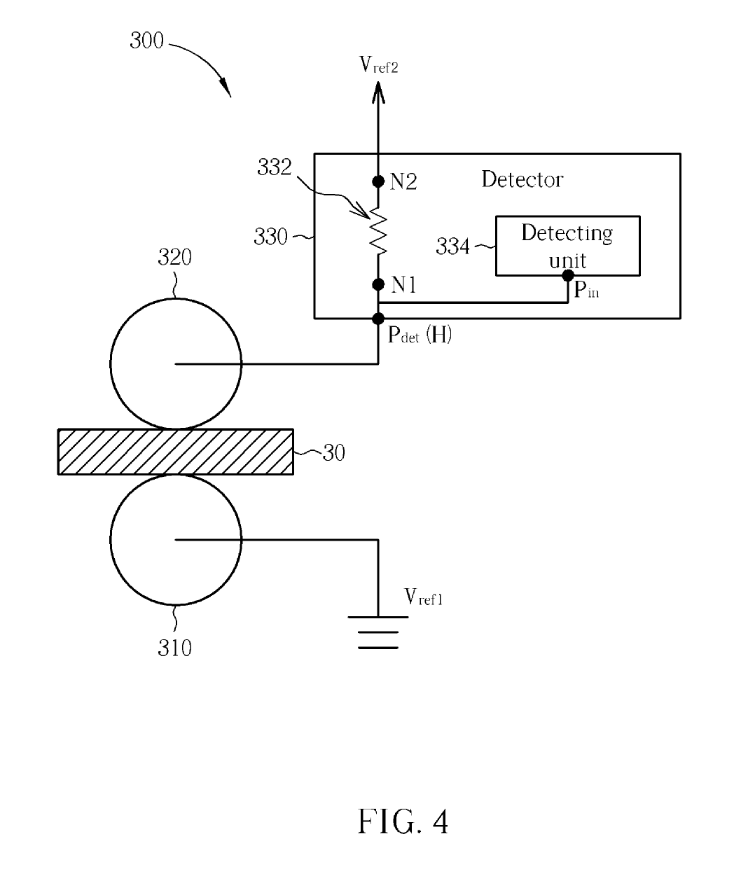

Please continue to refer to FIG. 3. When there is no non-conductive print media between the first and second conductive units 310, 320, the first and second conductive units 310, 320 are electrically connected to each other and a closed loop is formed between the first reference voltage level Vref1 and the second reference voltage level Vref2. In this scenario, the voltage level of the detecting port Pdet is approximately equal to the first reference voltage level Vref1. Please refer to FIG. 4. FIG. 4 is a diagram illustrating that there is a non-conductive print media 30 in the print media detecting module 300. The first and second conductive units 310, 320 in the print media detecting module 300 are both implemented by conductive rollers for moving the non-conductive print media 30; this is, however, for illustrative purposes and not a limitation of the prevent invention. When the first and second conductive units 310, 320 move the non-conductive print media 30 between them, the non-conductive print media 30 disconnects the first conductive unit 310 from the second conductive unit 320 and an open loop is formed between the first reference voltage level Vref1 and the second reference voltage level Vref2. In this scenario, the voltage level of the detecting port Pdet is approximately equal to the second reference voltage level Vref2.

In this embodiment, the first reference voltage level Vref1 is at ground, and the second reference voltage level Vref2 is a positive voltage source. When there is no non-conductive print media between the first and second conductive units 310, 320, the voltage level of the detecting port Pdet is at a low voltage level (i.e., ground voltage level). When there is a non-conductive print media between the first and second conductive units 310, 320, the voltage level of the detecting port Pdet is at a high voltage level (i.e., the voltage level of the positive voltage source). Therefore, if the detector 330 detects that the voltage level of the detecting port Pdet switches from the low voltage level to the high voltage level, the detector 330 can determine that there is a non-conductive print media entered between the first and second conductive units 310, 320.

Please note that, in this embodiment, the second reference voltage level Vref2 (i.e., the voltage level of the positive voltage source) is higher than the first reference voltage level Vref1 (i.e., ground voltage level); this is, however, for illustrative purposes and not a limitation of the prevent invention. In other embodiments, the second reference voltage level Vref2 can be lower than the first reference voltage level Vref1. In this scenario, when there is no non-conductive print media between the first and second conductive units 310, 320, the voltage level of the detecting port Pdet is at a high voltage level. When there is a non-conductive print media between the first and second conductive units 310, 320, the voltage level of the detecting port Pdet is at a low voltage level. Therefore, if the detector 330 detects that the voltage level of the detecting port Pdet switches from the high voltage level to the low voltage level, the detector 330 can determine that there is a non-conductive print media entered between the first and second conductive units 310, 320. This alternative design also falls within the scope of the present invention.

Please note that, in this embodiment, the electrical characteristic detected by the detector 330 in the print media detecting module 300 is a voltage level; this is, however, for illustrative purposes and not a limitation of the prevent invention. In other embodiments, the electrical characteristic can be a current value. That is, when there is no non-conductive print media between the first and second conductive units 310, 320, the first and second conductive units 310, 320 are electrically connected to each other and a closed loop is formed between the first reference voltage level Vref1 and the second reference voltage level Vref2. In this scenario, the current value flowing through the impedance unit 332 does not equal zero. When the first and second conductive units 310, 320 move the non-conductive print media 30 between them, the non-conductive print media 30 disconnects the first conductive unit 310 from the second conductive unit 320 and an open loop is formed between the first reference voltage level Vref1 and the second reference voltage level Vref2. In this scenario, the current value flowing through the impedance unit 332 at this time is equal to zero. Therefore, if the detector 330 detects that the current value flowing through the impedance unit 332 switches to zero, the detector 330 can determine that there is a non-conductive print media entered between the first and second conductive units 310, 320. After reading the above-mentioned description, how to design the detector 330 to detect current values should be readily appreciated by those skilled in the art, so further description is omitted here for the sake of brevity.

Compared with the conventional method of detecting print media in a dye diffusion thermal transfer printer, the print media detecting module of the present invention can detect non-conductive print media with the help of the first and second conductive units (e.g., conductive rollers); thus, the print media detecting module of the present invention can be used in a dye diffusion thermal transfer printer to detect a transparent print media, which is also a non-conductive print media, for printing the transparent print media correctly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A print media detecting module, comprising:
a first conductive unit, coupled to a first reference voltage level;
a second conductive unit; and
a detector, having a detecting port coupled to the second conductive unit and a second reference voltage level, for referring to an electrical characteristic of the detecting port to detect whether there is a non-conductive print media between the first and second conductive units that causes the first conductive unit to not be electrically connected to the second conductive unit;
wherein the first and second conductive units in an initial state are electrically connected to each other, and the first reference voltage level is different from the second reference voltage level.

2. The print media detecting module of claim 1, wherein the detector comprises:
an impedance unit, having a first end and a second end respectively coupled to the detecting port and the second reference voltage level; and
a detecting unit, having an input end coupled to the detecting port, for detecting whether the non-conductive print media is between the first and second conductive units according to the electrical characteristic of the detecting port.

3. The print media detecting module of claim 2, wherein the impedance unit is a resistor.

4. The print media detecting module of claim 1, wherein the electrical characteristic is a voltage level.

5. The print media detecting module of claim 4, wherein the second reference voltage level is higher than the first reference voltage level; when the voltage level of the detecting port is at a high voltage level, the detector determines that the non-conductive print media is between the first and second conductive units; and when the voltage level of the detecting port is at a voltage level lower than the high voltage level, the detector determines that there is no non-conductive print media between the first and second conductive units.

6. The print media detecting module of claim 4, wherein the second reference voltage level is lower than the first reference voltage level; when the voltage level of the detecting port is at a low voltage level, the detector determines that the non-conductive print media is between the first and second conductive units; and when the voltage level of the detecting port is at a voltage level higher than the low voltage level, the detector determines that there is no non-conductive print media between the first and second conductive units.

7. The print media detecting module of claim 1, wherein the first conductive unit and the second conductive unit are respectively a roller.

8. The print media detecting module of claim 7, being disposed in a printer.

9. The print media detecting module of claim 8, wherein the printer is a dye diffusion thermal transfer printer.

10. The print media detecting module of claim 1, wherein the non-conductive print media is made of a transparent material.
